(19) United States
(12) Patent Application Publication
(10) Pub. No.: US 2012/0032277 A1
(43) Pub. Date: Feb. 9, 2012

(54) SEMICONDUCTOR DEVICE

(75) Inventor: Kazutaka MANABE, Tokyo (JP)

(73) Assignee: ELPIDA MEMORY, INC., Tokyo (JP)

(21) Appl. No.: 13/195,615

(22) Filed: Aug. 1, 2011

(30) Foreign Application Priority Data
Aug. 3, 2010 (JP) 2010-174369

(51) Int. Cl. H01L 29/78

(52) U.S. Cl. 257/408; 257/E29.266

(57) ABSTRACT

A semiconductor device includes a MOS transistor. The MOS transistor includes a pair of first, second, and third impurity diffusion regions. The second impurity diffusion regions have a first conductive type and are provided in a semiconductor substrate in opposite sides of the first impurity diffusion region. The impurities concentration of the first conductive type in the second impurity diffusion regions is higher than the impurities concentration of the first conductive type in the first impurity diffusion regions. The third impurity diffusion regions have a second conductive type and are provided in the semiconductor substrate such that it contacts not the second impurity diffusion regions, but the first impurity diffusion regions.

This application is based upon and claims the benefit of priority from Japanese Patent Application No. 2010-174369, filed on Aug. 3, 2010, the disclosure of which is incorporated herein in its entirety by reference.

### BACKGROUND OF THE INVENTION

1. Field of the Invention

The present invention relates to a semiconductor device.

2. Background ART

With advancement in micronization technology, the short channel effects of a MOS transistor become obvious. In order to prevent such short channel effects, as disclosed in JP2001-160621, it is well-known that a technique of forming a pocket region using impurities having a conductive type that is opposite to that of impurities for forming source and drain. An exemplary N-channel MOS transistor including a pocket region is schematically shown in FIG. 10.

As shown in FIG. 10, an isolation region 22 is formed in a semiconductor substrate 21 made of P-type silicon. A gate electrode 23 is formed on a main surface of the semiconductor substrate 21 with a gate insulating film 20 interposed therebetween. The side surfaces of the gate electrode 23 are covered with sidewalls 26.

With the introduction of N-type impurities in the semiconductor substrate 21, extension regions 25 and SD regions 27 are formed. The concentration of the N-type impurities in the extension regions 25 is set to be lower than concentration of the N-type impurities in the SD regions 27. The extension regions 25 and the SD regions 27 serve to source and drain of the MOS transistor.

Pocket regions 29 are formed in the semiconductor substrate to surround the whole of the extension regions 25 and the SD regions 27, using P-type impurities. Accordingly, the short channel effects of the MOS transistor are prevented.

Further, for the purpose of obtaining a high performance MOS transistor, a technique of forming a gate insulating film using a high-k film (high dielectric film) was developed. As disclosed in JP2009-27002, in forming the gate insulating film including the high-k film, it is considered that the gate electrode is preferably formed using a method called a damascene gate process. The damascene gate process is a process that impurity diffusion regions serving as source and drain are first formed, and then a gate insulating film and a gate electrode are formed in series.

### SUMMARY OF THE INVENTION

In one embodiment, there is provided a semiconductor device, comprising:

a MOS transistor,

the MOS transistor comprising:
a semiconductor substrate;
a gate insulating film and a gate electrode sequentially formed on the semiconductor substrate;
a pair of first impurity diffusion regions having a first conductive type and formed in the semiconductor substrate in opposite sides of the gate electrode;
a pair of second impurity diffusion regions having the first conductive type and formed in the semiconductor substrate in opposite sides of the pair of the first impurity diffusion regions, the second impurity diffusion regions having impurities concentration of the first conductive type higher than impurities concentration of the first conductive type in the first impurity diffusion regions; and
a pair of third impurity diffusion regions having a second conductive type and formed in the semiconductor substrate, the pair of the third impurity diffusion regions contacting with the pair of the first impurity diffusion regions, respectively and not contacting with the pair of the second impurity diffusion regions.

In another embodiment, there is provided a semiconductor device, comprising:

a MOS transistor,

the MOS transistor comprising:
a semiconductor substrate;
a gate insulating film and a gate electrode sequentially formed on the semiconductor substrate;
sidewalls formed on opposite side surfaces of the gate electrode;
a pair of first impurity diffusion regions having a first conductive type and formed in the semiconductor substrate under at least the sidewalls;
a pair of second impurity diffusion regions having the first conductive type and formed in the semiconductor substrate in opposite sides of the gate electrode and the sidewalls, the respective second impurity diffusion region contacting with the respective first impurity diffusion region and having impurities concentration of the first conductive type higher than impurities concentration of the first conductive type in the first impurity diffusion region; and
a pair of third impurity diffusion regions having a second conductive type and formed in the semiconductor substrate under the sidewalls and the gate insulating film, the third impurity diffusion regions contacting with the first impurity diffusion regions, respectively and not contacting with the second impurity diffusion regions.

In another embodiment, there is provided a semiconductor device, comprising:

a MOS transistor,

the MOS transistor comprising:
a semiconductor substrate;
a gate insulating film on the semiconductor substrate;
a gate electrode on the gate insulating film;
a first impurity diffusion region having a first conductive type in the semiconductor substrate under the gate electrode;
a second impurity diffusion region having the first conductive type in the semiconductor substrate, the second impurity diffusion region contacting with a side of the first impurity diffusion region, and a concentration of the second impurity diffusion region being higher than a concentration of the first impurity diffusion region; and
a third impurity diffusion region having a second conductive type in the semiconductor substrate, the third impurity diffusion region contacting with the other side of the first impurity diffusion region, and being separated from the second diffusion impurity region.

### BRIEF DESCRIPTION OF THE DRAWINGS

The above features and advantages of the present invention will be more apparent from the following description of certain preferred embodiments taken in conjunction with the accompanying drawings, in which:

FIG. 1 is a view showing one process of manufacturing method an exemplary semiconductor device according to the present invention;

FIG. 2 is a view showing one process of manufacturing method an exemplary semiconductor device according to the present invention;

FIG. 3 is a view showing one process of manufacturing method an exemplary semiconductor device according to the present invention;

FIG. 4 is a view showing one process of manufacturing method an exemplary semiconductor device according to the present invention;

FIG. 5 is a view showing one process of manufacturing method an exemplary semiconductor device according to the present invention;

FIG. 6 is a view showing one process of manufacturing method an exemplary semiconductor device according to the present invention;

FIG. 7 is a view showing one process of manufacturing method an exemplary semiconductor device according to the present invention;

FIG. 8 is a view showing an exemplary semiconductor device according to the present invention;

FIG. 9 is a graphical diagram showing a concentration profile of impurities of the semiconductor device of FIG. 8; and

FIG. 10 is a view showing a semiconductor device according to the related art.

In the drawings, reference numerals have the following meanings: 20; gate insulating film, 1, 21; semiconductor substrate, 2, 22; isolation region, 3; dummy gate insulating film, 4; dummy gate electrode, 5, 25; extension region, 6, 26; sidewall, 7, 27; source and drain, 8; first interlayer insulating film, 9, 29; pocket region, 10; gate insulating film, 11, 23; gate electrode, 12; second interlayer insulating, 13; contact plug, 14; lead wiring

### DETAILED DESCRIPTION OF THE PREFERRED EMBODIMENTS

to The invention will be now described herein with reference to illustrative embodiment. Those skilled in the art will recognize that many alternative embodiments can be accomplished using the teachings of the present invention and that the invention is not limited to the embodiment illustrated for explanatory purposes.

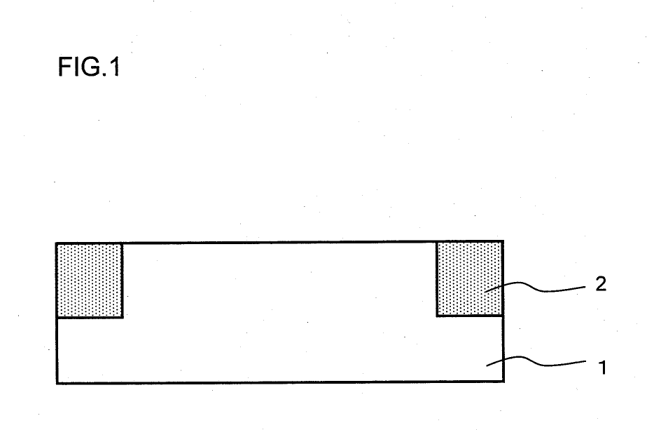

A method of manufacturing an N-channel MOS transistor according to the present invention will be now described herein with reference to illustrative embodiments. FIGS. 1-8 are schematic cross-sectional views showing a procedure of the manufacturing method of the embodiments.

As shown in FIG. 1, an isolation region 2 is formed in a semiconductor substrate 1 made of P-type silicon by embedding a insulating film using a STI method. A region defined by the isolation region 2 becomes an active region of the MOS transistor. Meanwhile, in a region where the N-channel transistor is to be formed, P-type well may be formed by introducing P-type impurities such as boron (B) into the semiconductor substrate 1.

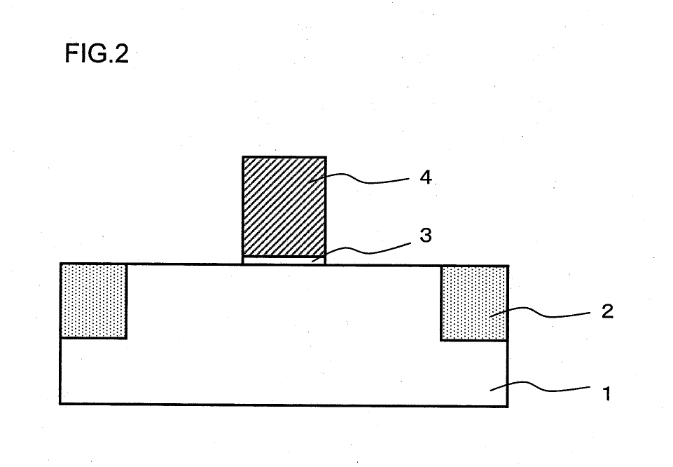

As shown in FIG. 2, a dummy gate insulating 3 made of silicon oxide (SiO₂) and a dummy gate electrode 4 made of polysilicon are stacked on the semiconductor substrate 1, and then are patterned into a shape of the gate electrode.

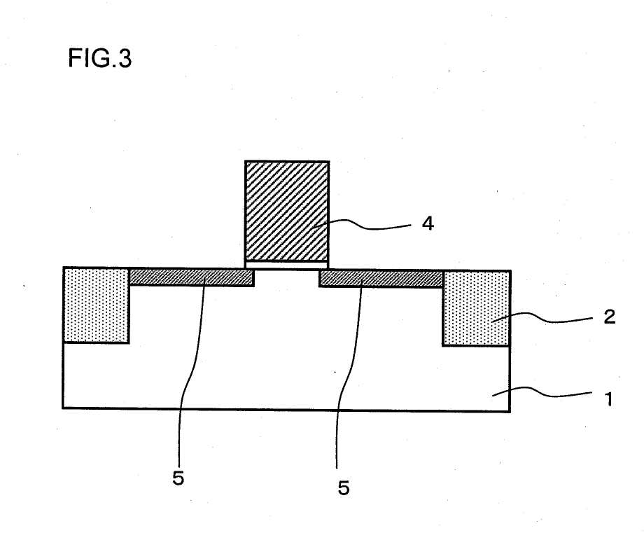

As shown in FIG. 3, N-type impurities such as arsenic (As), phosphor (P), etc. are ion-implanted into the semiconductor substrate 1 to form N-type extension regions 5. Ion implantation is performed on the surface of the semiconductor substrate 1 in a vertical direction (implantation angle: 0 degree). An exemplary implantation condition may be energy of 2-10 KeV and doses of 5×10¹²-5×10¹³ atoms/cm². The impurity concentration of the extension regions 5 are set to be lower than impurity concentration of SD regions to be formed subsequently.

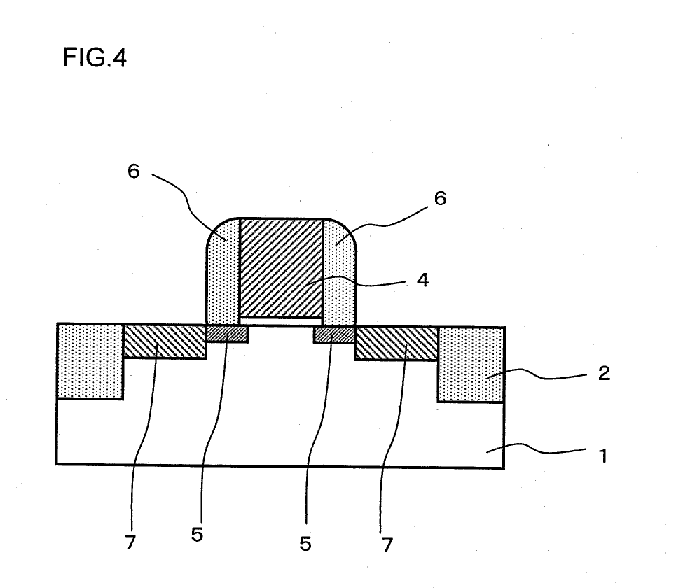

As shown in FIG. 4, a silicon nitride film is stacked and etched-back to form sidewalls 6 that cover the side surfaces of the gate electrode. Subsequently, N-type impurities such as arsenic (As), phosphor (P), etc. are ion-implanted into the semiconductor substrate 1 to form N-type SD regions 7. Hereinafter, the SD regions are defined as the impurity diffusion regions formed in opposite sides of the gate electrode and sidewalls in the semiconductor substrate. The SD regions correspond to a second impurity diffusion region. Ion implantation is performed on the surface of the semiconductor substrate 1 in a vertical direction (implantation angle: 0 degree). An exemplary implantation condition may be energy of 10-30 KeV and doses of 1×10¹⁴-5×10¹⁵ atoms/cm². The impurity concentration of the SD regions 7 is set to be higher than impurity concentration of the extension regions 5 (the extension regions 5 positioned under the sidewalls and the gate insulating film correspond to first impurity diffusion regions) that is first formed.

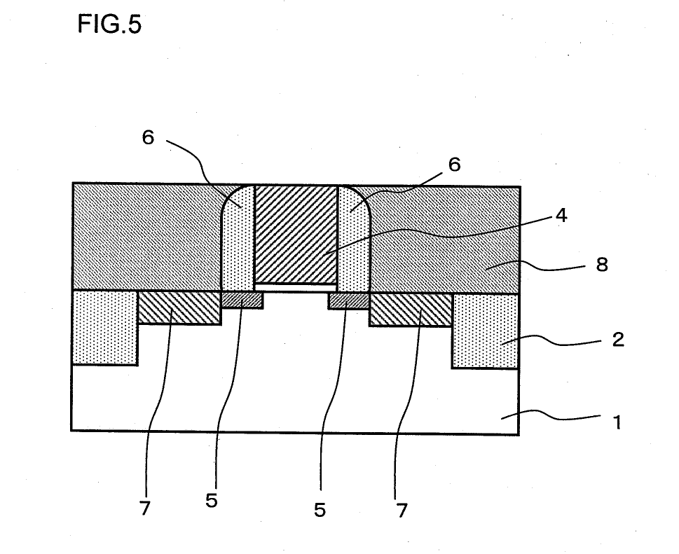

As shown in FIG. 5, silicon oxide is stacked using a CVD method, and is planarized using a CMP method. When the upper surface of the dummy gate electrode 4 is exposed, the CMP method is stopped to carry out. Thereby a first interlayer insulating film 8 is formed.

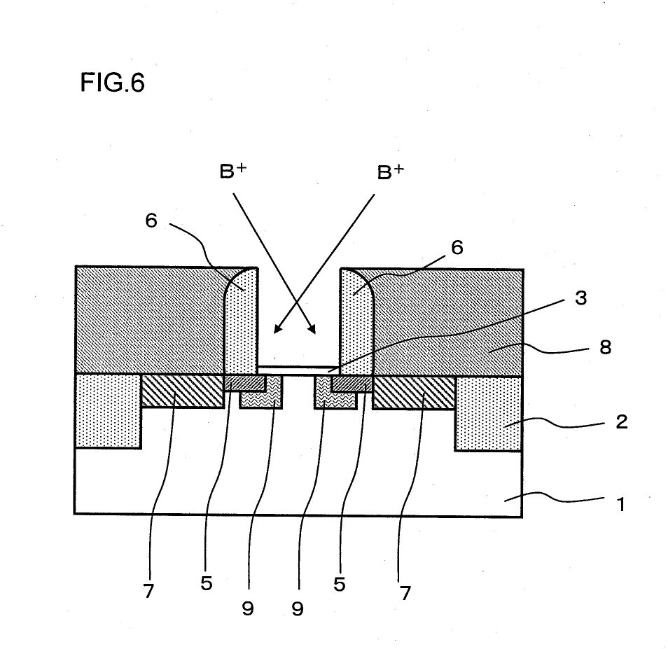

As shown in FIG. 6, the dummy gate electrode 4 is removed by etching. Next, P-type impurities such as boron (B) or the like are ion-implanted into the semiconductor substrate 1 in an oblique direction, to form P-type pocket regions 9 (which correspond to third impurity diffusion regions). Ion implantation is performed at a predetermined implantation angle to the surface of the semiconductor substrate 1. With adjustment of the implantation angle, regions where the pocket regions 9 are to be formed can be adjusted. Thereby, there are formed the pocket regions 9 which do not contact the SD regions 7, but contact the outside of the extension regions 5 such that the pocket regions 9 surround the extension regions 5. In addition, here, the pocket regions 9 may also be formed in the semiconductor substrate 1 under the sidewalls. An exemplary implantation condition may be the implantation angle of 5-25 degrees, energy of 3-15 KeV and doses of 1×10¹³-1×10¹⁴ atoms/cm². If a P-type well was first formed in a region where a MOS transistor is to be formed, the impurity concentration of the pocket regions 9 is set to be higher than impurity concentration of the P-type well.

Next, annealing is performed in the temperature of 850-950 degrees centigrade by a rapid heat treatment method using e.g. a lamp anneal apparatus so as to activate the impurities, thereby forming source and drain of the MOS transistor. In the meantime, when setting an implantation angle and energy to form the pocket regions 9, the implantation condition is preferably set in consideration of lateral thermal diffusion of the pocket regions 9 which occur due to the annealing process.

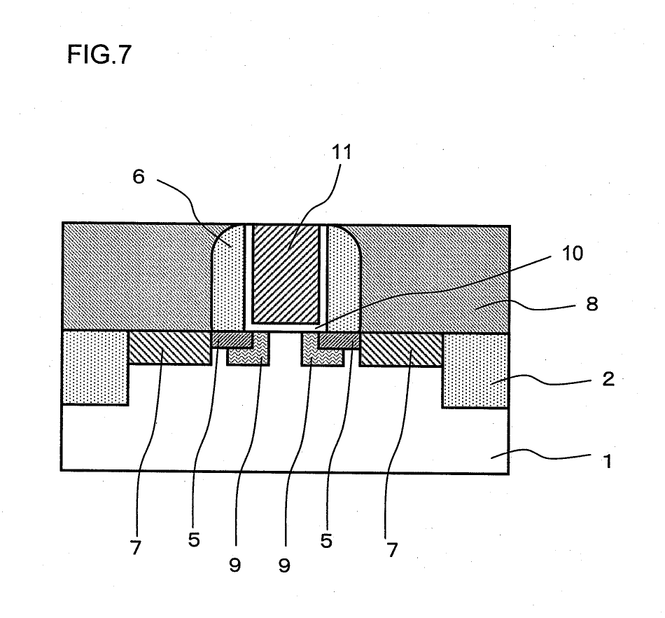

As shown in FIG. 7, the dummy gate insulating film 3 is removed by wet-etching using e.g. diluted hydrofluoric acid, thereby to expose the surface of the semiconductor substrate 1. Next, a high-k film (high dielectric film) is stacked in thickness of 3-5 nm, to form a gate insulating film 10. The high-k film may include for example a high dielectric film such as HfSiON, HfO₂, Al₂O₃, ZrO₂, or a hybrid film thereof (e.g. a hybrid film of a silicon oxide film and a HfSiON film).

Subsequently, a conductive film is embedded in a recess that is generated by formerly removing the dummy gate electrode 4, and is CMP processed, thereby to form a gate electrode 11. The conductive film adapted to the gate electrode 11 may include for example at least one metal film selected from a group consisting of a Ni silicide (Ni₃Si, NiSi, NiSi₂) film, a Hf silicide (HfSi₂) film, a titanium nitride (TiN) film. The conductive film may use a hybrid film composed of different materials.

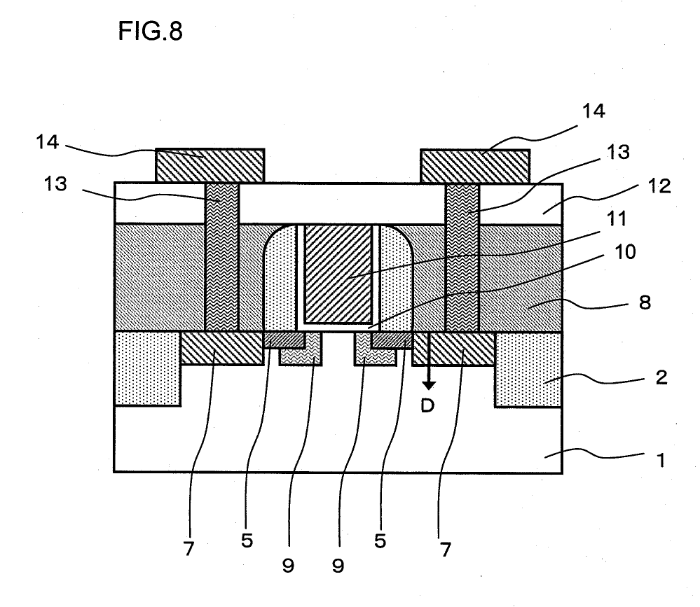

As shown in FIG. 8, a second interlayer insulating film 12 is formed so as to cover the upper surface of the gate electrode 11, using silicon oxide or the like. Subsequently, contact plugs 13 connecting to the SD regions and lead wires 14, a contact plug (not shown) connecting to the gate electrode and a lead wire (not shown) are formed thereby to complete a MOS transistor.

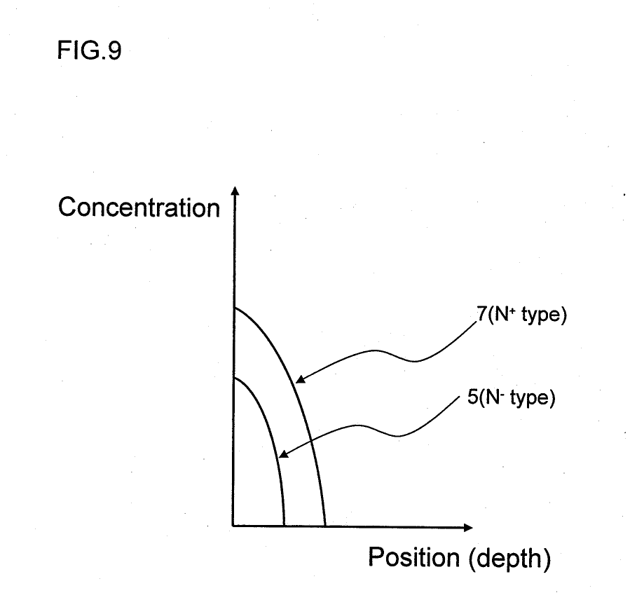

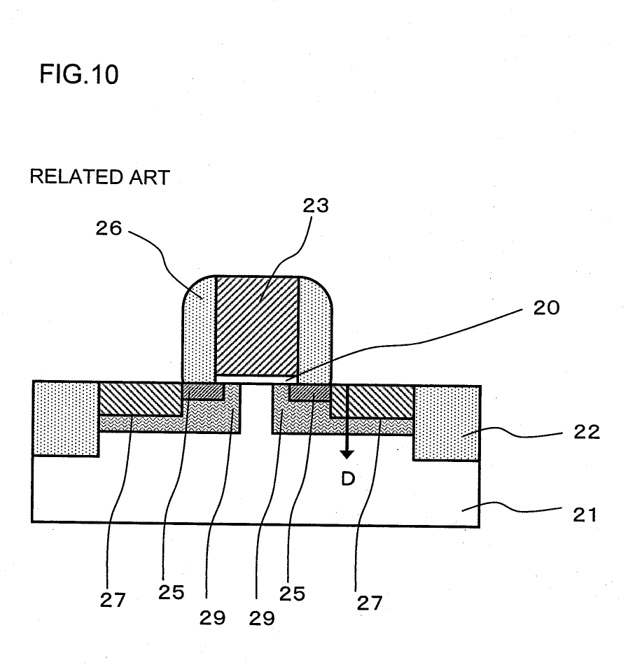

FIG. 9 is a graphical diagram schematically showing a concentration profile of impurities at a portion indicated by an arrow D shown in FIG. 8. The horizontal axis of FIG. 9 indicates a position (depth) from the surface of the semiconductor substrate with respect to the arrow D. The vertical axis of FIG. 9 indicates a relative concentration of the respective impurities. As shown in FIGS. 8 and 9, in the present embodiment, there is no P-type pocket regions 9 surrounding the outside of the N-type SD regions 7, so that parasitic capacitance due to a P-N junction between the SD regions 7 and the pocket regions 9 can be prevented from occurring. Since the extension regions 5 have an impurity concentration lower than impurity concentration of the SD regions 7, the parasitic capacitance due to the P-N junction between the extension regions 5 and the pocket regions 9 is small, as compared to the related structure (FIG. 10), the parasitic capacitance can be greatly to reduced.

While the above embodiment has illustrated the case of the N-channel MOS transistor, a P-channel MOS transistor can be similarly formed by changing the conductive type of impurities for ion implantation, specifically, the extension regions and the SD regions may be formed using P-type impurities and the pocket regions may be formed using N-type impurities. In case of using a P-type semiconductor substrate, an N-type well is first formed in a region where a P-channel MOS transistor is to be formed. Also in case of forming the P-channel MOS transistor, pocket regions are formed by a method similar to the above-mentioned method, thereby forming a MOS transistor with reduced parasitic capacitance.

Moreover, also in case of using a conventional silicon oxide film instead of the high-k dielectric film as the gate insulating film, the present invention can be adapted by forming the gate electrode using the damascene method process.

It is apparent that the present invention is not limited to the above embodiments, but may be modified and changed without departing from the scope and spirit of the invention.

In addition, while not specifically claimed in the claim section, the applications reserve the right to include in the claim section at any appropriate time the following method:

1. A method of manufacturing a semiconductor device, comprising:

sequentially forming a dummy gate insulating film and a dummy gate electrode on a semiconductor substrate;

implanting first conductive type impurities into the semiconductor substrate in opposite sides of the dummy gate electrode, to form first regions;

forming sidewalls on both side surfaces of the dummy gate electrode;

implanting first conductive type impurities into the semiconductor substrate in opposite sides of the dummy gate electrode and the sidewalls, thereby

(A) converting the first regions, positioned under the sidewalls and the dummy gate insulating film in the semiconductor substrate, into a pair of first impurity diffusion regions having a first conductive type, and

(B) forming a pair of second impurity diffusion regions having a first conductive type in the semiconductor substrate in opposite sides of the dummy gate electrode and the sidewalls;

removing the dummy gate electrode;

implanting second conductive type impurities into two regions of the semiconductor substrate under the dummy gate insulating film, to form a pair of third impurity diffusion regions having a second conductive type, the third impurity diffusion regions contacting with the first impurity diffusion regions, respectively and not contacting with the second impurity diffusion regions;

removing the dummy gate insulating film to expose the semiconductor substrate between the pair of sidewalls; and

sequentially forming a gate insulating film and a gate electrode on the exposed semiconductor substrate, to obtain a MOS transistor.

2. The method according to the item 1,

wherein in forming the third impurity diffusion regions, the second conductive type impurities are implanted in an oblique direction with respect to a vertical direction to a main surface of the semiconductor substrate.

3. The method according to the item 2,

wherein in forming the third impurity diffusion regions, the second conductive type impurities are implanted at an angle of 5-25 degrees with respect to the vertical direction to the main surface of the semiconductor is substrate.

4. The method according to the item 1,

wherein the gate insulating film includes a high dielectric film.

5. The method according to the item 4,

wherein the high dielectric film is HfSiON film, HfO₂ film, Al₂O₃ film, or ZrO₂ film.

6. The method according to the item 1,

wherein the first conductive type is an N-type,

the second conductive type is a P-type, and

the MOS transistor is an N-channel MOS transistor.

7. The method according to the item 1,

wherein the first conductive type is a P-type,

the second conductive type is an N-type, and

the MOS transistor is a P-channel MOS transistor.

What is claimed is:

1. A semiconductor device, comprising:
a MOS transistor,
the MOS transistor comprising:
a semiconductor substrate;
a gate insulating film and a gate electrode sequentially formed on the semiconductor substrate;
a pair of first impurity diffusion regions having a first conductive type and formed in the semiconductor substrate in opposite sides of the gate to electrode;
a pair of second impurity diffusion regions having the first conductive type and formed in the semiconductor substrate in opposite sides of the pair of the first impurity diffusion regions, the second impurity diffusion regions having impurities concentration of the first conductive type higher than impurities concentration of the first conductive type in the first impurity diffusion regions; and
a pair of third impurity diffusion regions having a second conductive type and formed in the semiconductor substrate, the pair of the third impurity diffusion regions contacting with the pair of the first impurity diffusion regions, respectively and not contacting with the pair of the second impurity diffusion regions.

2. The semiconductor device according to claim 1,
wherein sidewalls are formed above at least a portion of the first impurity diffusion regions, the respective sidewall contacting with a respective side surface of the gate electrode.

3. The semiconductor device according to claim 1,
wherein the third impurity diffusion regions are formed in the semiconductor substrate under the gate electrode and the sidewalls.

4. The semiconductor device according to claim 1,
wherein the gate insulating film includes a high dielectric film.

5. The semiconductor device according to claim 4,
wherein the high dielectric film is HfSiON film, HfO₂ film, Al₂O₃ film, or ZrO₂ film.

6. The semiconductor device according to claim 1,
wherein the first conductive type is an N-type,
is the second conductive type is a P-type, and
the MOS transistor is an N-channel MOS transistor.

7. The semiconductor device according to claim 1,
wherein the first conductive type is a P-type,
the second conductive type is an N-type, and
the MOS transistor is a P-channel MOS transistor.

8. The semiconductor device according to claim 1,
wherein a depth of the third impurity diffusion region is greater than a depth of the first impurity diffusion region.

9. The semiconductor device according to claim 1,
wherein the gate electrode comprises at least one metal film selected from a group consisting of a Ni silicide (Ni₃Si, NiSi, NiSi₂) film, a Hf silicide (HfSi₂) film, and a titanium nitride (TiN) film.

10. A semiconductor device, comprising:
a MOS transistor,
the MOS transistor comprising:
a semiconductor substrate;
to a gate insulating film and a gate electrode sequentially formed on the semiconductor substrate;
sidewalls formed on opposite side surfaces of the gate electrode;
a pair of first impurity diffusion regions having a first conductive is type and formed in the semiconductor substrate under at least the sidewalls;
a pair of second impurity diffusion regions having the first conductive type and formed in the semiconductor substrate in opposite sides of the gate electrode and the sidewalls, the respective second impurity diffusion region contacting with the respective first impurity diffusion region and having impurities concentration of the first conductive type higher than impurities concentration of the first conductive type in the first impurity diffusion region; and
a pair of third impurity diffusion regions having a second conductive type and formed in the semiconductor substrate under the sidewalls and the gate insulating film, the third impurity diffusion regions contacting with the first impurity diffusion regions, respectively and not contacting with the second impurity diffusion regions.

11. The semiconductor device according to claim 10,
wherein the gate insulating film includes a high dielectric film.

12. The semiconductor device according to claim 11,
wherein the high dielectric film is HfSiON film, HfO₂ film, Al₂O₃ film, or ZrO₂ film.

13. The semiconductor device according to claim 10,
wherein the first conductive type is an N-type,
the second conductive type is a P-type, and
the MOS transistor is an N-channel MOS transistor.

14. The semiconductor device according to claim 10,
wherein the first conductive type is a P-type,
the second conductive type is an N-type, and
the MOS transistor is a P-channel MOS transistor.

15. The semiconductor device according to claim 10,
wherein a depth of the third impurity diffusion region is greater than a depth of the first impurity diffusion region.

16. The semiconductor device according to claim 10,
wherein the gate electrode comprises at least one metal film selected from a group consisting of a Ni silicide (Ni₃Si, NiSi, NiSi₂) film, a Hf silicide (HfSi₂) film, and a titanium nitride (TiN) film.

17. A semiconductor device, comprising:
a MOS transistor,
the MOS transistor comprising:
a semiconductor substrate;
a gate insulating film on the semiconductor substrate;
a gate electrode on the gate insulating film;
a first impurity diffusion region having a first conductive type in the semiconductor substrate under the gate electrode;
a second impurity diffusion region having the first conductive type in the semiconductor substrate, the second impurity diffusion region contacting with a side of the first impurity diffusion region, and a concentration of the second impurity diffusion region being higher than a concentration of the first impurity diffusion region; and
a third impurity diffusion region having a second conductive type in the semiconductor substrate, the third impurity diffusion region contacting with the other side of the first impurity diffusion region, and being separated from the second impurity diffusion region.

18. The semiconductor device according to claim 17,
wherein a sidewall is formed above a portion of the first impurity diffusion region, the sidewall contacting with a side surface of the gate electrode.

19. The semiconductor device according to claim 17,
wherein the third impurity diffusion region is formed in the semiconductor substrate under the gate electrode and the sidewall.

20. The semiconductor device according to claim 17,
wherein the gate insulating film includes a high dielectric film.
